(19) United States
(12) Patent Application Publication
(10) Pub. No.: US 2023/0197009 A1
(43) Pub. Date: Jun. 22, 2023

(54) Organic Light Emitting Diode Display Device Including Low Level Line

(71) Applicant: LG Display Co., Ltd., Seoul (KR)

(72) Inventors: Eui-Tae Kim, Paju-si (KR); Jeong-Hwan Lee, Paju-si (KR)

(21) Appl. No.: 17/961,543

(22) Filed: Oct. 6, 2022

(30) Foreign Application Priority Data
Dec. 22, 2021 (KR) 10-2021-0184946

(51) Int. Cl. G09G 3/3258

(52) U.S. Cl. CPC G09G 3/3258; G09G 2300/0426; G09G 2300/0452; G09G 2300/0842; G09G 2310/0262

(57) ABSTRACT

An organic light emitting diode display device includes: a substrate having a plurality of subpixels; a driving transistor in each of the plurality of subpixels on the substrate; a light emitting diode in each of the plurality of subpixels on the driving transistor; and a low level line between the driving transistor and the light emitting diode in each of the plurality of subpixels.

### CROSS REFERENCE TO RELATED APPLICATIONS

The present application claims the priority benefit of Republic of Korea Patent Application No. 10-2021-0184946 filed in Republic of Korea on Dec. 22, 2021, which is hereby incorporated by reference herein in its entirety.

### BACKGROUND

### Technical Field

The present disclosure relates to an organic light emitting diode display device, and more particularly, to an organic light emitting diode display device including a low level line where a coupling between a gate electrode and an anode is minimized by disposing the low level line between the gate electrode and the anode of adjacent subpixels.

### Discussion of the Related Art

Recently, with the advent of an information-oriented society and as the interest in information displays for processing and displaying a massive amount of information and the demand for portable information media have increased, a display field has rapidly advanced. Thus, various light and thin flat panel display devices have been developed and highlighted.

Among the various flat panel display devices, an organic light emitting diode (OLED) display device is an emissive type device and does not include a backlight unit used in a non-emissive type device such as a liquid crystal display (LCD) device. As a result, the OLED display device has advantages in a viewing angle, a contrast ratio and a power consumption to be applied to various fields.

In the OLED display device, red, green and blue light emitting diodes emit red, green and blue colored lights, respectively, to display an image. The light of a shorter wavelength has a higher energy. As a result, when red, green and blue subpixels have the same area as each other, a lifetime of a blue emitting layer of the blue subpixel becomes shorter than a lifetime of red and green emitting layers of the red and green subpixels.

To solve the above problems, a technology where the blue emitting layer of the blue subpixel is formed to have an area larger than an area of the red and green emitting layers of the red and green subpixels has been suggested. However, since a location of the emitting layer of each subpixel and a location of a pixel circuit part therebelow do not coincide with each other, deterioration such as a crosstalk due to a coupling occurs.

Specifically, when the blue emitting layer of the blue subpixel having a largest area is disposed to overlap the pixel circuit of the green subpixel, an anode of the blue subpixel and a gate electrode of a driving transistor of the green subpixel overlap each other to cause a coupling. As a result, a voltage of the gate electrode of the driving transistor of the green subpixel is changed due to a voltage of the anode of the blue subpixel, and the green subpixel does not display a predetermined luminance due to the blue subpixel.

### SUMMARY

Accordingly, the present disclosure is directed to an organic light emitting diode display device that substantially obviate one or more of the problems due to limitations and disadvantages of the related art.

An object of the present disclosure is to provide an organic light emitting diode display device including a low level line where a coupling between a gate electrode and an anode in adjacent subpixels is minimized, a line width of the low level line of a non-emission area is reduced and a high speed driving and a narrow bezel are obtained by disposing the low level line between the gate electrode and the anode.

Another object of the present disclosure is to provide an organic light emitting diode display device where a coupling between a gate electrode and an anode in adjacent subpixels is minimized, deterioration such as a crosstalk is prevented and a high speed driving is obtained by forming a storage electrode to cover a gate electrode.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, an organic light emitting diode display device includes: a substrate having a plurality of subpixels; a driving transistor in each of the plurality of subpixels on the substrate; a light emitting diode in each of the plurality of subpixels on the driving transistor; and a low level line between the driving transistor and the light emitting diode in each of the plurality of subpixels.

In another aspect, an organic light emitting diode display device includes: a substrate having first and second subpixels; a driving transistor in each of the first and second subpixels on the substrate; a light emitting diode in each of the first and second subpixels on the driving transistor; and a low level line between a gate electrode of the driving transistor of the first subpixel and an anode of the light emitting diode of the second subpixel.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view showing an organic light emitting diode display device including a low level line according to an embodiment of the present disclosure;

FIG. 2 is a circuit diagram showing a subpixel of an organic light emitting diode display device according to an embodiment of the present disclosure;

FIG. 3 is a view showing a plurality of signals used in a subpixel of an organic light emitting diode display device according to an embodiment of the present disclosure;

FIG. 4 is a plan view showing three adjacent subpixels of an organic light emitting diode display device according to an embodiment of the present disclosure;

FIG. 5A is a cross-sectional view taken along a line Va-Va′ of FIG. 4;

FIG. 5B is a cross-sectional view taken along a line Vb-Vb′ of FIG. 4;

FIG. 5C is a cross-sectional view taken along a line Vc-Vc′ of FIG. 4; and

FIG. 6 is a view showing a parasitic capacitance of each subpixel of an organic light emitting diode display device according to an embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the present disclosure is only defined by scopes of claims.

A shape, a size, a ratio, an angle, and a number disclosed in the drawings for describing embodiments of the present disclosure are merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted. In a case where terms “comprise,” “have,” and “include” described in the present specification are used, another part may be added unless a more limiting term, such as “only,” is used. The terms of a singular form may include plural forms unless referred to the contrary.

In construing an element, the element is construed as including an error or tolerance range even where no explicit description of such an error or tolerance range.

In describing a position relationship, when a position relation between two parts is described as, for example, “on,” “over,” “under,” or “next,” one or more other parts may be disposed between the two parts unless a more limiting term, such as “just” or “direct(ly),” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, an organic light emitting diode display device including a low level line according to embodiments of the present disclosure will be described in detail with reference to the accompanying drawings. In the following description, same reference numerals designate same elements throughout. When a detailed description of well-known functions or configurations related to this document is determined to unnecessarily cloud a gist of the inventive concept, the detailed description thereof will be omitted or will be made brief.

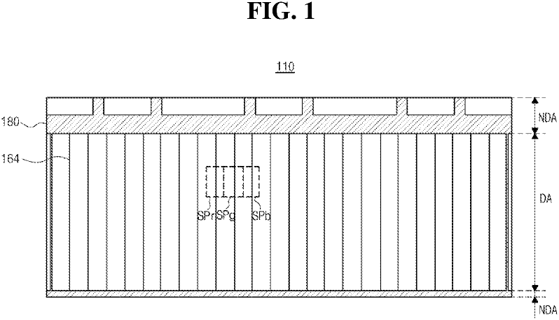

FIG. 1 is a plan view showing an organic light emitting diode display device including a low level line according to an embodiment of the present disclosure.

In FIG. 1, an organic light emitting diode (OLED) display device 110 according to an embodiment of the present disclosure includes a display area DA where a plurality of subpixels are disposed and a non-display area NDA where a plurality of link lines are disposed.

For example, the display area DA may be disposed in a central portion of the OLED display device 110, and the non-display area NDA may be disposed in an edge portion adjacent to two long sides of the OLED display device 110.

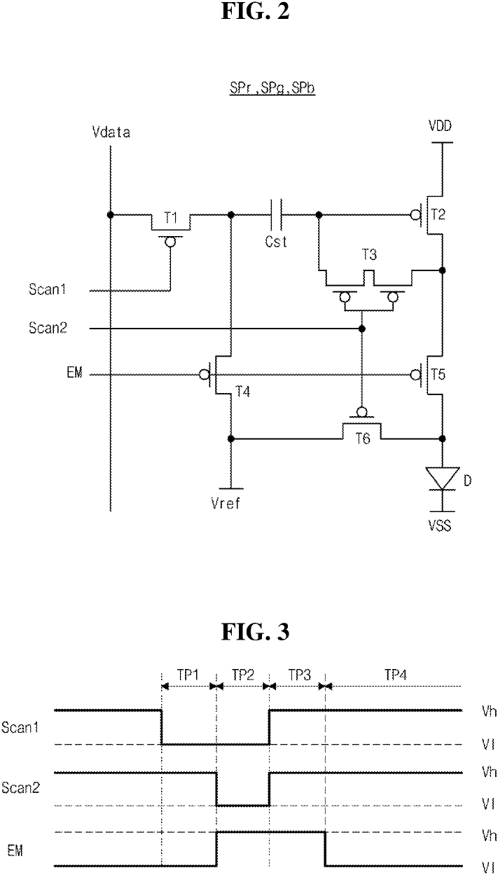

The plurality of subpixels may include red, green and blue subpixels SPr, SPg and SPb, and the plurality of link lines may include a high level link line (not shown) transmitting a high level voltage VDD (of FIG. 2) to the plurality of subpixels, low level link lines 180 transmitting a low level voltage VSS (of FIG. 2) to the plurality of subpixels, a data link line (not shown) transmitting a data voltage Vdata (of FIG. 2) to the plurality of subpixels, a gate link line transmitting a gate first voltage Scan1 (of FIG. 2) and a gate second voltage Scan2 (of FIG. 2) to the plurality of subpixels and an emission link line transmitting an emission voltage EM (of FIG. 2) to the plurality of subpixels.

When the OLED display device 110 has a gate-in-panel (GIP) type where a gate driving unit is formed in a display panel through the same process as the plurality of subpixels, the gate link line and the emission link line of the non-display area NDA may be omitted.

A low level line 164 corresponding to each of the plurality of subpixels is disposed in the display area DA. The low level line 164 is connected to the low level link line 180 of the non-display area NDA to transmit the low level voltage VSS to the plurality of subpixels and may be disposed parallel to a short side of the OLED display device 110.

The low level line 164 and the low level link line 180 may have the same layer and the same material as each other.

The subpixel and the operation of the OLED display device 110 will be illustrated with reference to drawings.

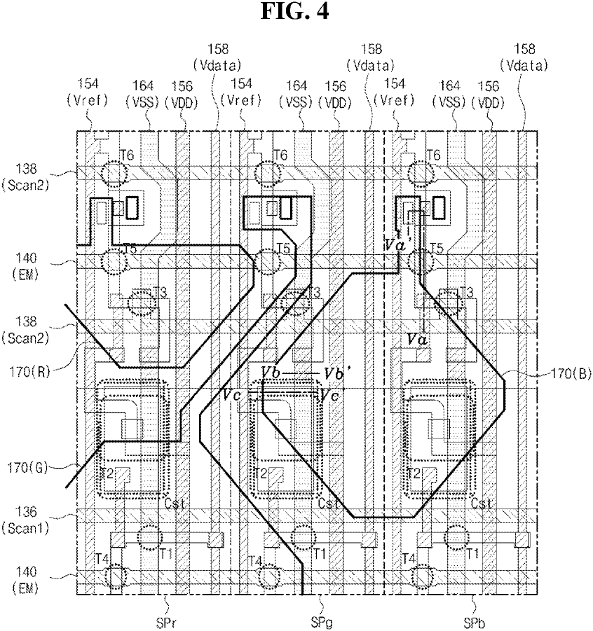

FIG. 2 is a circuit diagram showing a subpixel of an organic light emitting diode display device according to an embodiment of the present disclosure, and FIG. 3 is a view showing a plurality of signals used in a subpixel of an organic light emitting diode display device according to an embodiment of the present disclosure.

In FIG. 2, each of red, green and blue subpixels SPr, SPg and SPb of the OLED display device 110 according an embodiment of the present disclosure includes first to sixth transistors T1 to T6, a storage capacitor Cst and a light emitting diode D.

For example, the first to sixth transistors T1 to T6 may have a positive (P) type.

The first transistor T1 as a switching transistor is switched according to a gate first voltage Scan1. A gate electrode of the first transistor T1 is connected to the gate first voltage Scan1, a source electrode of the first transistor T1 is connected to a first capacitor electrode of the storage capacitor Cst and a source electrode of the fourth transistor T4, and a drain electrode of the first transistor T1 is connected to a data voltage Vdata.

The second transistor T2 as a driving transistor is switched according to a voltage of a second capacitor electrode of the storage capacitor Cst. A gate electrode of the second transistor T2 is connected to the second capacitor electrode of the storage capacitor Cst and a drain electrode of the third transistor T3, a source electrode of the second transistor T2 is connected to a high level voltage VDD, and a drain electrode of the second transistor T2 is connected to a source electrode of the third transistor T3 and a source electrode of the fifth transistor T5.

The third transistor T3 is switched according to a gate second voltage Scan2. A gate electrode of the third transistor T3 is connected to the gate second voltage Scan2, a source electrode of the third transistor T3 is connected to the drain electrode of the second transistor T2 and the source electrode of the fifth transistor T5, and the drain electrode of the third transistor T3 is connected to the gate electrode of the second transistor T2 and the second capacitor electrode of the storage capacitor Cst.

Although the third transistor T3 has a dual gate type in an embodiment of FIG. 2, the third transistor T3 may have a single gate type in another embodiment.

The fourth transistor T4 is switched according to an emission voltage EM. A gate electrode of the fourth transistor T4 is connected to the emission voltage EM, the source electrode of the fourth transistor T4 is connected to the source electrode of the first transistor T1 and the first capacitor electrode of the storage capacitor Cst, and a drain electrode of the fourth transistor T4 is connected to a drain electrode of the sixth transistor T6 and a reference voltage Vref.

The fifth transistor T5 as an emission transistor is switched according to the emission voltage EM. A gate electrode of the fifth transistor T5 is connected to the emission voltage EM, the source electrode of the fifth transistor T5 is connected to the drain electrode of the second transistor T2 and the source electrode of the third transistor T3, and a drain electrode of the fifth transistor T5 is connected to a source electrode of the sixth transistor T6 and an anode of the light emitting diode D.

The sixth transistor T6 is switched according to the gate second voltage Scan2. A gate electrode of the sixth transistor T6 is connected to the gate second voltage Scan, the source electrode of the sixth transistor T6 is connected to the drain electrode of the fifth transistor T5 and the anode of the light emitting diode D, and the drain electrode of the sixth transistor T6 is connected to the drain electrode of the fourth transistor T4 and the reference voltage Vref.

The storage capacitor Cst stores the data voltage Vdata and a threshold voltage Vth. The first capacitor electrode of the storage capacitor Cst is connected to the source electrode of the first transistor T1 and the source electrode of the fourth transistor T4, and the second capacitor electrode of the storage capacitor Cst is connected to the gate electrode of the second transistor T2 and the drain electrode of the third transistor T3.

The light emitting diode D is connected between the fifth and sixth transistors T5 and T6 and the low level voltage VSS and emits a light having a luminance proportional to a current of the second transistor T2. The anode of the light emitting diode D is connected to the drain electrode of the fifth transistor T5 and the source electrode of the sixth transistor T6, and the cathode of the light emitting diode D is connected to the low level voltage VSS.

In FIG. 3, during a first time period TP1 as an initial period, the gate first voltage Scan1 and the emission voltage EM have a low level voltage Vl and the gate second voltage Scan2 has a high level voltage Vh such that the first, fourth and fifth transistors T1, T4 and T5 are turned on, the sixth transistor is turned off. As a result, the first capacitor electrode of the storage capacitor Cst has the first reference voltage Vref such that the gate electrode of the second transistor T2 is initialized.

During a second time period TP2 as a sensing period, the gate first voltage Scan1 and the gate second voltage Scan2 have the low level voltage Vl and the emission voltage EM has the high level voltage Vh such that the first, third and sixth transistors T1, T3 and T6 are turned on and the fourth and fifth transistors T4 and T5 are turned off. As a result, the first capacitor electrode of the storage capacitor Cst has the data voltage Vdata, the second capacitor electrode of the storage capacitor Cst has a sum (Vdata-Vref+Vth) of a difference (Vdata-Vref) between the data voltage Vdata and the reference voltage Vref and the threshold voltage Vth such that the threshold voltage Vth is stored in the storage capacitor Cst.

During a third time period TP3 as a holding period, the gate first voltage Scan1, the gate second voltage Scan2 and the emission voltage EM have the high level voltage Vh such that the first, third, fourth, fifth and sixth transistors T1, T3, T4, T5 and T6 are turned off. As a result, the first capacitor electrode of the storage capacitor Cst has the data voltage Vdata and the second capacitor electrode of the storage capacitor Cst has the sum (Vdata-Vref+Vth) of the difference (Vdata-Vref) between the data voltage Vdata and the reference voltage Vref and the threshold voltage Vth.

During a fourth time period TP4 as an emission period, the gate first voltage Scan1 and the gate second voltage Scan2 have the high level voltage Vh and the emission voltage EM has the low level voltage Vl such that the first, third and sixth transistors T1, T3 and T6 are turned off and the fourth and fifth transistors T5 are turned on. As a result, a current proportional to a square of a value ((Vdata-Vref+Vth-VDD)-Vth = Vdata-Vref-VDD) obtained by subtracting the threshold voltage Vth from a gate-source voltage Vgs flows in the second transistor T2 such that the light emitting diode D emits a light of a luminance corresponding to the current flowing the second transistor T2.

In the OLED display device 110 according to an embodiment of the present disclosure, the light emitting diode D emits a light according to operation of the first to sixth transistors T1 to T6 and the storage capacitor Cst to display an image. A shift of the threshold voltage or a deterioration of the light emitting diode D according to an operation time may be compensated due to the subpixels SP, and a luminance may be adjusted by driving the light emitting diode D according to a duty ratio corresponding to an emission time.

In the OLED display device 110, emitting layers of the plurality of subpixels may have different areas based on a lifetime of the emitting layers of the plurality of subpixels.

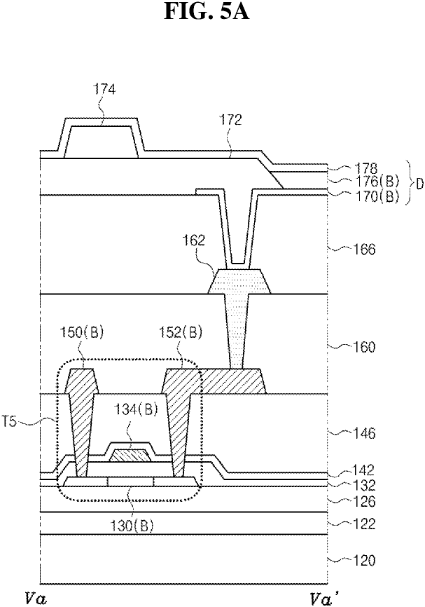

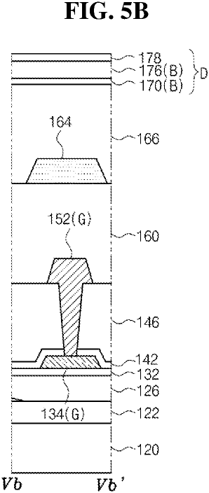

FIG. 4 is a plan view showing three adjacent subpixels of an organic light emitting diode display device according to an embodiment of the present disclosure, FIG. 5A is a cross-sectional view taken along a line Va-Va′ of FIG. 4, FIG. 5B is a cross-sectional view taken along a line Vb-Vb′ of FIG. 4, and FIG. 5C is a cross-sectional view taken along a line Vc-Vc′ of FIG. 4.

In FIG. 4, the OLED display device 110 according to an embodiment of the present disclosure includes a plurality of gate first lines 136 transmitting the gate first voltage Scan1, a plurality of gate second lines 138 transmitting the gate second voltage Scan2, a plurality of emission lines 140 transmitting the emission voltage EM, a plurality of reference lines 154 transmitting the reference voltage Vref, a plurality of low level lines 164 transmitting the low level voltage VSS, a plurality of high level lines 156 transmitting the high level voltage VDD and a plurality of data lines 158 transmitting the data voltage Vdata. The low level line 164 may be located between the driving transistor T2 and the light emitting diode D in each of the plurality of subpixels.

The plurality of gate first lines 136, the plurality of gate second lines 138 and the plurality of emission lines 140 are disposed in a horizontal direction parallel to a long side of the OLED display device 110, and the plurality of reference lines 154, the plurality of low level lines 164, the plurality of high level lines 156 and the plurality of data lines 158 are disposed in a vertical direction parallel to a short side of the OLED display device 110. The gate second line 138 and the emission line 140 cross the reference line 154 and the data line 158 to define each of the plurality of subpixels.

For example, in each of the red, green and blue subpixels SPr, SPg and SPb, the gate second line 138, the emission line 140, the gate second line 138, the gate first line 136 and the emission line 140 may be sequentially disposed along the vertical direction, and the reference line 154, the low level line 164, the high level line 156 and the data line 158 may be sequentially disposed along the horizontal direction.

Each of the red, green and blue subpixels SPr, SPg and SPb includes the first to sixth transistors T1 to T6, the storage capacitor Cst and the light emitting diode D.

To compensate for a relatively short lifetime of the blue light emitting diode D, the blue light emitting diode D is formed to have an area greater than an area of each of the red and green light emitting didoes D. As a result, the anode 166 of the red light emitting diode D is disposed in the red subpixel SPr, the anode 166 of the green light emitting diode D is disposed in the red and green subpixels SPr and SPg, and the anode 166 of the blue light emitting diode D is disposed in the green and blue subpixels SPg and SPb.

Since the anode 166 of the light emitting diode D of the blue subpixel SPb overlaps the gate electrode 134 of the second transistor T2 as a driving transistor of the green subpixel SPg, a coupling between the anode of the blue subpixel SPb and the gate electrode 134 of the green subpixel SPg is generated such that the green subpixel SPg displays an abnormal luminance.

In the OLED display device 110 according to an embodiment of the present disclosure, since the low level line 164 where the low level voltage VSS is applied is disposed between the anode 166 of the light emitting diode D of the blue subpixel SPb and the gate electrode 134 of the second transistor T2 of the green subpixel SPg, a coupling between the anode 166 of the blue subpixel SPb and the gate electrode 134 of the green subpixel SPg is minimized.

In addition, since a storage electrode 144 completely covers the gate electrode 134 such that the gate electrode 134 is not exposed outside the storage electrode 144, a coupling between the anode 166 of the blue subpixel SPb and the gate electrode 134 of the green subpixel SPg is further minimized.

In FIGS. 5A to 5C, a first buffer layer 122 is disposed on the entire substrate 120, and a light shielding layer 124 is disposed in a region of the second transistor T2 on the first buffer layer 122.

The substrate 120 may include a glass or polyimide (PI), the first buffer layer 122 may have a double layer of an inorganic insulating material such as silicon nitride (SiNx) or silicon oxide (SiO2), and the light shielding layer 124 may include an opaque metallic material such as molybdenum (Mo).

The first buffer layer 122 may block a moisture permeating from a lower portion, and the light shielding layer 124 may block a light incident from the lower portion and may collect a charge accumulated in the lower portion.

The light shielding layer 124 may be connected to the gate electrode 134 to receive the gate voltage.

A second buffer layer 126 is disposed on the entire light shielding layer 124, and a semiconductor layer 130 is disposed in a region of each of the first to sixth transistors T1 to T6.

The second buffer layer 126 may include an inorganic insulating material such as silicon oxide (SiO2), and the semiconductor layer 130 may include a semiconductor material such as silicon or an oxide semiconductor material. When the semiconductor layer 130 may include polycrystalline silicon, the semiconductor layer 130 may have an active region of a central portion and a source-drain region of side portions.

A gate insulating layer 132 is disposed on the entire semiconductor layer 130, and the gate electrode 134 is disposed on the gate insulating layer 132 over the semiconductor layer 130.

The gate insulating layer 132 may include an inorganic insulating material such as silicon oxide (SiO2), and the gate electrode 134 may include a metallic material such as molybdenum (Mo).

The gate electrode 134 may be disposed in a region corresponding to the first to sixth transistors T1 to T6 and the storage capacitor Cst.

The gate first line 136, the gate second line 138 and the emission line 140 are disposed on the gate insulating layer 132. The gate first line 136, the gate second line 138 and the emission line 140 may have the same layer and the same material as the gate electrode 134.

A first interlayer insulating layer 142 is disposed on the entire gate electrode 134, for example, on the gate electrode 134 of the second transistor T2, and the storage electrode 144 is disposed in a region of the storage capacitor Cst on the first interlayer insulating layer 142. The storage electrode 144 may be disposed on the first interlayer insulating layer 142 corresponding to the gate electrode 134 of the second transistor T2. The gate electrode 134 in the region of the storage capacitor Cst may be the gate electrode 134 of the second transistor T2 or an extending portion thereof.

The first interlayer insulating layer 142 may include an inorganic insulating material such as silicon nitride (SiNx), and the storage electrode 144 may include a metallic material such as molybdenum (Mo).

The gate electrode 134 functioning as a first capacitor electrode, the first interlayer insulating layer 142, and the storage electrode 144 functioning as a second capacitor electrode constitute the storage capacitor Cst. The storage electrode 144 has an area greater than an area of the gate electrode 134 such that the storage electrode 144 completely covers the gate electrode 134 and the gate electrode 134 is not exposed outside the storage electrode 144. The storage capacitor Cst may be connected to the driving transistor T2 in each of the plurality of subpixels.

FIG. 5C shows the gate electrode 134, the first interlayer insulating layer 142 and the storage electrode 144 of the storage capacitor Cst of the green subpixel SPg.

A second interlayer insulating layer 146 is disposed on the entire storage electrode 144, a source electrode 150 and a drain electrode 152 are disposed in a region of the first to sixth transistors T1 to T6 on the second interlayer insulating layer 146. For example, the drain electrode 152 of the third transistor T3 connected to the gate electrode 134 of the second transistor T2 may be disposed on the second interlayer insulating layer 146.

The second interlayer insulating layer may have a double layer of an inorganic insulating material such as silicon nitride (SiNx) or silicon oxide (SiO2), and the source electrode 150 and the drain electrode 152 may have a triple layer of a metallic material such as titanium (Ti) and aluminum (Al).

The source electrode 150 and the drain electrode 152 are connected to the side portions, respectively, of the semiconductor layer 130 through contact holes of the gate insulating layer 132, the first interlayer insulating layer 142 and the second interlayer insulating layer 146. The semiconductor layer 130, the gate electrode 134, the source electrode 150 and the drain electrode 152 constitute each of the first to sixth transistors T1 to T6.

The drain electrode 152 of the third transistor T3 is connected to the gate electrode 134 of the second transistor T2 through a contact hole of the first interlayer insulating layer 142 and the second interlayer insulating layer 146.

FIG. 5A shows the semiconductor layer 130, the gate electrode 134, the source electrode 150 and the drain electrode 152 of the fifth transistor T5 of the blue subpixel SPb, and FIG. 5B shows the drain electrode 152 of the third transistor T3 and the gate electrode 134 of the second transistor T2.

The reference line 154, the high level line 156 and the data line 158 are disposed on the second interlayer insulating layer, and the reference line 154, the high level line 156 and the data line 158 may include the same layer and the same material as the source electrode 150 and the drain electrode 152.

A first planarizing layer 160 is disposed on the entire source electrode 150 and the drain electrode 152, and a connecting electrode 162 and the low level line 164 are disposed in a region of the light emitting diode D on the first planarizing layer 160. The first planarizing layer 160 may be disposed on the drain electrode 152 of the third transistor T3.

The first planarizing layer 160 may include an organic insulating material such as photoacryl, and the connecting electrode 162 and the low level line 164 may include a triple layer of a metallic material such as titanium (Ti) and aluminum (Al).

The connecting electrode 162 is connected to the drain electrode 152 of the fifth transistor T5 through a contact hole of the first planarizing layer 160, and the low level line 164 completely covers the drain electrode 152 of the third transistor T3 of the green subpixel SPg and the gate electrode 134 of the second transistor T2 such that the drain electrode 152 and the gate electrode 134 are not exposed outside the low level line 164. The fifth transistor T5 may be connected to the light emitting diode D through a connecting electrode 162. The low level line 164 may be disposed on the first planarizing layer 160 corresponding to the gate electrode 134 of the second transistor T2.

The connecting electrode 162 and the low level line 164 may include the same layer and the same material as each other.

A second planarizing layer 166 is disposed on the entire connecting electrode 162 and the low level line 164, and the anode 170 is disposed in a region of the light emitting diode D on the second planarizing layer 166.

The second planarizing layer 166 may include an organic insulating material such as photoacryl, and the anode 170 may have a triple layer of a transparent conductive material such as indium tin oxide (ITO) and a metallic material such as silver palladium copper (AgPdCu) alloy.

The anode 170 is connected to the connecting electrode 162 through a contact hole of the second planarizing layer 166. The anode 170 may be disposed on the second planarizing layer 166 corresponding to the low level line 164.

A bank layer 172 is disposed on an edge portion of the anode 170, and an emitting layer 176 is disposed on the anode 170 exposed through an opening of the bank layer 172.

The bank layer 172 may include an organic insulating material such as polyimide (PI), and the emitting layer 176 may emit red, green and blue colored lights in the red, green and blue subpixels SPr, SPg and SPb, respectively.

A spacer 174 is disposed on the bank layer 172, and a cathode 178 is disposed on the entire spacer 174.

The spacer 174 may include an organic insulating material such as polyimide (PI).

The cathode 178 may be connected to the low level line 164 in the non-display area NDA to receive the low level voltage VSS. Alternatively, the low level voltage VSS supplied to the cathode 178 may be applied to the low level line 164.

The anode 170, the emitting layer 176 and the cathode 178 constitute the light emitting diode D. The light emitting diode D may be disposed in each of the plurality of subpixels on the driving transistor T2.

Although the anode 170 is disposed as a lower layer and the cathode 178 is disposed as an upper layer in an embodiment of FIGS. 5A to 5C, the anode may be disposed as an upper layer and the cathode may be disposed as a lower layer in another embodiment.

In FIG. 5B, the anode 166 of the light emitting diode D of the blue subpixel SPb is disposed to overlap the gate electrode 134 of the second transistor T2 as a driving transistor of the green subpixel SPg.

As a result, a coupling between the anode 166 of the light emitting diode D of the blue subpixel SPb and the gate electrode 134 of the second transistor T2 of the green subpixel SPg due to a parasitic capacitance Cpara is generated, and a voltage of the gate electrode 134 of the second transistor T2 of the green subpixel SPg is changed due to a voltage applied to the anode 166 of the light emitting diode D of the blue subpixel SPb such that the green subpixel SPg may display an abnormal luminance.

In the OLED display device 110 according to an embodiment of the present disclosure, since the low level line 164 having the low level voltage is disposed between the anode 166 of the light emitting diode D of the blue subpixel SPb and the gate electrode 134 of the second transistor T2 of the green subpixel SPg, a parasitic capacitance Cpara between the anode 166 of the light emitting diode D of the blue subpixel SPb and the gate electrode 134 of the second transistor T2 of the green subpixel SPg is minimized. As a result, a coupling is minimized, and the abnormal luminance display of the green subpixel SPg is prevented.

In addition, since the parasitic capacitance Cpara is minimized, a capacitance of the storage capacitor Cst for blocking an influence of the parasitic capacitance Cpara is reduced. Since a load for a signal such as the gate voltage and the data voltage is minimized, a high speed driving such as about 120 Hz is easily obtained.

Moreover, since the low level line of the edge portion of the short side is omitted or a width thereof is reduced by disposing the low level line 164 in each of the red, green and blue subpixels SPr, SPg and SPb, the non-display area NDA is minimized to obtain a narrow bezel.

In FIG. 5C, the storage electrode 144 of the storage capacitor Cst of the green subpixel SPg completely covers the gate electrode 134 (or the extending portion thereof) of the second transistor T2 such that the gate electrode 134 of the second transistor T2 is not exposed outside the storage electrode 144.

The storage electrode 144 of the storage capacitor Cst of the green subpixel SPg overlaps the anode 170 of the light emitting diode D of the blue subpixel SPb. As a result, when the storage electrode 144 of the storage capacitor Cst of the green subpixel SPg exposes the gate electrode 134 of the second transistor T2, a coupling is generated between the gate electrode 134 of the second transistor T2 of the green subpixel SPg and the anode 170 of the light emitting diode D of the blue subpixel SPb and the green subpixel SPg may display an abnormal luminance.

In the OLED display device 110 according to an embodiment of the present disclosure, since the storage electrode 144 of the storage capacitor Cst of the green subpixel SPg connected to the first and fourth transistors T1 and T4 completely covers the gate electrode 134 of the second transistor T2 and the gate electrode 134 is not exposed outside the storage electrode 144 of the storage capacitor Cst of the green subpixel SPg, a parasitic capacitance Cpara between the anode 166 of the light emitting diode D of the blue subpixel SPb and the gate electrode 134 of the second transistor of the green subpixel SPg is further minimized and a coupling is further minimized. As a result, an abnormal luminance display of the green subpixel SPg is prevented.

In addition, since the parasitic capacitance Cpara is further minimized, a capacitance of the storage capacitor Cst for blocking an influence of the parasitic capacitance Cpara is reduced. As a result, a load for a signal such as the gate voltage and the data voltage is minimized, and a high speed driving such as about 120 Hz is easily obtained.

Minimization of the parasitic capacitance will be illustrated with reference to a drawing.

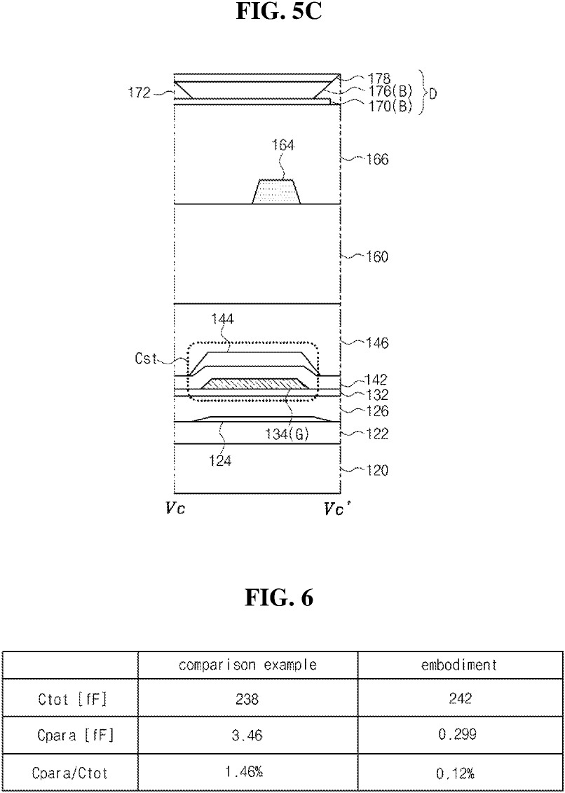

FIG. 6 is a view showing a parasitic capacitance of each subpixel of an organic light emitting diode display device according to an embodiment of the present disclosure.

In FIG. 6, a comparison example where a low level line 164 is not disposed between an anode 166 of a light emitting diode D of a blue subpixel SPb and a gate electrode 134 of a second transistor T2 of a green subpixel SPg has a total capacitance Ctot of about 238fF and a parasitic capacitance Cpara of about 3.46fF. The total capacitance Ctot is a sum of a gate-source capacitance, a capacitance of a storage capacitor Cst and the parasitic capacitance Cpara connected to the gate electrode 134 of the second transistor T2. A ratio of the parasitic capacitance Cpara to the total capacitance Ctot of the comparison example is about 1.46%.

An embodiment of the present disclosure where the low level line 164 is disposed between the anode 166 of the light emitting diode D of the blue subpixel SPb and the gate electrode 134 of the second transistor T2 of the green subpixel SPg has a total capacitance Ctot of about 242fF and a parasitic capacitance Cpara of about 0.299fF. The total capacitance Ctot is a sum of a gate-source capacitance, a capacitance of a storage capacitor Cst and the parasitic capacitance Cpara connected to the gate electrode 134 of the second transistor T2. A ratio of the parasitic capacitance Cpara to the total capacitance Ctot of the embodiment is about 0.12%.

In the embodiment of the present disclosure, a substrate having first and second subpixels may be included. The first subpixel may be the green subpixel SPg, and the second subpixel may be the blue subpixel SPb. In this case, the parasitic capacitance Cpara is reduced due to the low level line 164 between the anode 166 of the light emitting diode D of the blue subpixel SPb and the gate electrode 134 of the second transistor T2 of the green subpixel SPg. As a result, a coupling is reduced and an abnormal luminance display of the green subpixel SPg is prevented.

Further, in the embodiment of the present disclosure, the parasitic capacitance Cpara with respect to the total capacitance Ctot is reduced and the capacitance of the storage capacitor Cst constituting the total capacitance Ctot is reduced. As a result, a load of each subpixel with respect to a signal such as the data voltage is minimized, and a high speed driving such as about 120 Hz is easily obtained.

Consequently, in the OLED display device 110 according to an embodiment of the present disclosure, since the low level line is disposed between the gate electrode and the anode of the subpixel, a coupling between the gate electrode and the anode of the adjacent subpixel is minimized and a width of the low level line of the non-display area is reduced. As a result, a high speed driving and a narrow bezel are obtained.

Further, since the storage electrode completely covers and does not expose the gate electrode, a coupling between the gate electrode and the anode of the adjacent subpixel is minimized. As a result, deterioration such as a crosstalk is prevented and a high speed driving is obtained.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims.

What is claimed is:

1. An organic light emitting diode display device, comprising:
a substrate having a plurality of subpixels;
a driving transistor in each of the plurality of subpixels on the substrate;
a light emitting diode in each of the plurality of subpixels on the driving transistor; and
a low level line between the driving transistor and the light emitting diode in each of the plurality of subpixels.

2. The organic light emitting diode display device of claim 1, wherein the plurality of subpixels include red, green and blue subpixels, and
wherein the low level line is disposed between a gate electrode of the driving transistor of the green subpixel and an anode of the light emitting diode of the blue subpixel.

3. The organic light emitting diode display device of claim 2, wherein an anode of the light emitting diode of the red subpixel is disposed in the red subpixel,
wherein an anode of the light emitting diode of the green subpixel is disposed in the red and green subpixels, and
wherein the anode of the blue subpixel is disposed in the green and blue subpixels.

4. The organic light emitting diode display device of claim 1, wherein a low level voltage supplied to a cathode of the light emitting diode is applied to the low level line.

5. The organic light emitting diode display device of claim 1, further comprising a storage capacitor connected to the driving transistor in each of the plurality of subpixels,
wherein the storage capacitor includes a storage electrode which covers a gate electrode of the corresponding driving transistor.

6. The organic light emitting diode display device of claim 1, wherein each of the plurality of subpixels comprises:
a first transistor connected to a data line and switched according to a gate first voltage;
a storage capacitor connected to the first transistor and including first and second capacitor electrodes;
a second transistor as the driving transistor connected to a high level line and switched according to a voltage of the second capacitor electrode of the storage capacitor;
a third transistor connected to the storage capacitor and the second transistor and switched according to a gate second voltage;
a fourth transistor connected to the storage capacitor and a reference line and switched according to an emission voltage;
a fifth transistor connected to the second transistor and the light emitting diode and switched according to the emission voltage; and
a sixth transistor connected to the light emitting diode and the reference line and switched according to the gate second voltage.

7. The organic light emitting diode display device of claim 6, wherein the fifth transistor is connected to the light emitting diode through a connecting electrode, and
wherein the connecting electrode has a same layer and a same material as the low level line.

8. The organic light emitting diode display device of claim 6, wherein a first interlayer insulating layer is disposed on a gate electrode of the second transistor,
wherein a storage electrode is disposed on the first interlayer insulating layer corresponding to the gate electrode of the second transistor,
wherein a second interlayer insulating layer is disposed on the storage electrode,
wherein a drain electrode of the third transistor connected to the gate electrode of the second transistor is disposed on the second interlayer insulating layer,
wherein a first planarizing layer is disposed on the drain electrode of the third transistor,
wherein the low level line is disposed on the first planarizing layer corresponding to the gate electrode of the second transistor,
wherein a second planarizing layer is disposed on the low level line, and
wherein an anode of the light emitting diode is disposed on the second planarizing layer corresponding to the low level line.

9. The organic light emitting diode display device of claim 6, wherein the third transistor is further connected to the fifth transistor, the third transistor has a dual gate type, and the second gate voltage is applied to two gate electrodes of the third transistor.

10. The organic light emitting diode display device of claim 6, wherein during an initial period, the gate first voltage and the emission voltage have a low level voltage and the gate second voltage has a high level voltage,
during a sensing period after the initial period, the gate first voltage and the gate second voltage have the low level voltage and the emission voltage has the high level voltage,
during a holding period after the sensing period, the gate first voltage, the gate second voltage and the emission voltage have the high level voltage, and
during an emission period after the holding period, the gate first voltage and the gate second voltage have the high level voltage and the emission voltage has the low level voltage.

11. The organic light emitting diode display device of claim 6, further comprising a gate first line transmitting the gate first voltage, a gate second line transmitting the gate second voltage, and an emission line transmitting the emission voltage,
wherein the gate first line, the gate second line and the emission line are disposed in a horizontal direction parallel to a long side of the organic light emitting diode display device, and the reference line, the low level line, the high level line and the data line are disposed in a vertical direction parallel to a short side of the organic light emitting diode display device.

12. The organic light emitting diode display device of claim 11, wherein the gate second line, the emission line, the gate second line, the gate first line and the emission line are sequentially disposed along the vertical direction, and the reference line, the low level line, the high level line and the data line are sequentially disposed along the horizontal direction.

13. The organic light emitting diode display device of claim 5, wherein the storage electrode completely covers the gate electrode such that the gate electrode is not exposed outside the storage electrode.

14. The organic light emitting diode display device of claim 8, wherein the low level line completely covers the drain electrode of the third transistor and the gate electrode of the second transistor such that the drain electrode of the third transistor and the gate electrode of the second transistor are not exposed outside the low level line.

15. An organic light emitting diode display device, comprising:
a substrate having first and second subpixels;
a driving transistor in each of the first and second subpixels on the substrate;
a light emitting diode in each of the first and second subpixels on the driving transistor; and
a low level line between a gate electrode of the driving transistor of the first subpixel and an anode of the light emitting diode of the second subpixel.

16. The organic light emitting diode display device of claim 15, further comprising a storage capacitor connected to the driving transistor in each of the first and second subpixels,
wherein the storage capacitor includes a storage electrode which covers the gate electrode of the corresponding driving transistor.
